(19) United States
(12) Patent Application Publication
(10) Pub. No.: US 2018/0212204 A1
(43) Pub. Date: Jul. 26, 2018

(54) OLED DISPLAY PANEL AND METHOD FOR PACKAGING OLED DISPLAY PANEL

(71) Applicant: Wuhan China Star Optoelectronics Technology Co., Ltd., Wuhan, Hubei (CN)

(72) Inventor: Wei Yu, Wuhan, Hubei (CN)

(73) Assignee: Wuhan China Star Optoelectronics Technology Co., Ltd., Wuhan, Hubei (CN)

(21) Appl. No.: 15/327,129

(22) PCT Filed: Dec. 29, 2016
(86) PCT No.: PCT/CN2016/113048

§ 371 Date: Jan. 18, 2017

(30) Foreign Application Priority Data
Dec. 26, 2016 (CN) 201611215732.8

(51) Int. Cl. H01L 51/56; H01L 51/52

(52) U.S. Cl. CPC H01L 51/56; H01L 27/3206; H01L 51/5246

(57) ABSTRACT

Disclosed is an OLED display panel, which includes a substrate, an OLED device, a passivation layer, dam adhesive, fill adhesive, a cover plate and a first semipermeable membrane. The OLED device is arranged in the middle of the substrate and is covered by the passivation layer. The dam adhesive is arranged on peripheries of the cover plate. A side of the cover plate on which the dam adhesive is provided faces the substrate provided with the OLED. A sealed space is formed by the cover plate, the dam adhesive and the substrate. The first semipermeable membrane is arranged in the middle of the cover plate and located in the sealed space, and the fill adhesive is provided in the formed sealed space. The fill adhesive contacts the dam adhesive flawlessly, which prevents the dam adhesive from being damaged under the impact of the fill dam, thereby guaranteeing packaging effect of the OLED device.

### CROSS-REFERENCE TO RELATED APPLICATIONS

This application claims the priority of Chinese patent application CN201611215732.8, entitled “OLED display panel and method for packaging OLED display panel” and filed on Dec. 26, 2016, the entirety of which is incorporated herein by reference.

### FIELD OF THE INVENTION

The present disclosure relates to the field of liquid crystal display, and in particular, to an OLED display panel and a method for packaging an OLED display panel.

### BACKGROUND OF THE INVENTION

OLED (organic light-emitting diode) display devices are a new generation of display devices, in which an organic film is manufactured on an OLED substrate. The organic film is sandwiched between cathode and anode metal or between conductive layers. The manic film emits light when voltages are applied to the electrodes. Compared with a liquid crystal display device, the OLED display device has multiple advantages such as auto-luminescence, rapid response, wide viewing angle and high color saturation.

Water and oxygen in the air can oxidize active metal of a cathode of the OLED device, and can chemically react with organic materials, which can both cause malfunction of the OLED device. Therefore, effective packaging of an OLED device that can fully isolate the OLED device from water and oxygen is very important to prolonging of the service life of the OLED device.

Currently OLED packaging is mainly achieved through drying sheets and UV adhesive, surface packaging, glass cement packaging, thin-film packaging and the like. The adoption of dam & fill adhesives belongs to surface packaging, wherein the dam adhesive has a water and oxygen blocking function, the fill adhesive enables the OLED device to respond to external pressures effectively and block water and oxygen. An existing OLED display device has a structure as shown in FIG. 1, and comprises a substrate 1, an OLED device 2, a passivation layer 3, a fill adhesive 4, a dam adhesive 5 and a cover plate 6. The OLED device is arranged on the substrate and located in the middle of the substrate. Four lateral sides and an upper surface of the OLED device are covered by the passivation layer. The dam adhesive is arranged around the OLED device and the passivation layer. A height of the dam adhesive is larger than a sum of a thickness of the passivation layer and a thickness of the OLED device. The dam adhesive is covered by the cover plate. A sealed space is formed by the cover is plate, the dam adhesive and the substrate. The fill adhesive is injected into the sealed space to fill an hollow area therein. The important passivation layer arranged on the substrate can prevent direct contact of the fill adhesive and the OLED device which can affect device characteristics. The packaging method is flexible and convenient, can be flexibly adapted to products with different sizes, and thus it is a packaging method with great development potential.

In general, the packaging cover plate is first coated with the frame-shaped dam adhesive; then the fill adhesive is applied to the interior of the dam adhesive frame; then the substrate where the OLED device is manufactured and the packaging cover plate are aligned and pressed together and finally the dam adhesive and the fill adhesive are cured. However, during press fitting of the substrate and the cover plate, the fill adhesive gets into contact with the dam adhesive that is not completely cured as the fill adhesive disperses, which causes the dam adhesive to deform under impact, resulting in certain defects on an interface between the dam adhesive and the fill adhesive, which further affects the water and oxygen blocking property.

### SUMMARY OF THE INVENTION

The present disclosure aims to overcome the defect that a fill adhesive contacts with a dam adhesive that is not completely cured, which causes the dam adhesive to deform under impact, resulting in certain degree of defects on an interface between the dam adhesive and the fill adhesive, which then affects the water and oxygen blocking property. In other words, the present disclosure aims to provide a structure that enables the fill adhesive to contact with the dam adhesive flawlessly, preventing the dam adhesive from being damaged under the impact of the fill adhesive, and thus guaranteeing the OLED device packaging effect.

The objective of the present disclosure and the technical problem are realized and solved by adopting the technical solutions below.

An OLED display panel comprises a substrate, an OLED device, a passivation layer, a dam adhesive, a fill adhesive, a cover plate and a first semipermeable membrane. The OLED device is arranged in the middle of the substrate and covered by the passivation layer. The dam adhesive is arranged on peripheries of the cover plate. A side of the cover plate, on which the dam adhesive is provided, faces the substrate provided with the OLED device. A sealed space is formed by the cover plate, the dam adhesive and the substrate. The first semipermeable membrane is arranged in the middle of the cover plate and located in the sealed space, and the sealed space is filled with the fill adhesive.

In the OLED display panel, a size of the first semipermeable membrane is smaller than a size of a frame defined by the dam adhesive on the cover plate.

In the OLED display panel, a second semipermeable membrane is arranged in the middle of the first semipermeable membrane, and an area of the second semipermeable membrane is smaller than that of the first semipermeable membrane.

In the OLED display panel, the thickness of the second semipermeable membrane is larger than that of the first semipermeable membrane.

In the OLED display panel, a distance between the second semipermeable membrane and the passivation layer is not smaller than half of a height of the dam adhesive.

In the OLED display panel, the packaging method comprises:
(1) arranging the first semipermeable membrane in the middle of the cover plate;
(2) coating the packaging cover plate provided with the semipermeable membrane with a frame-shaped dam adhesive;
(3) coating the semipermeable membranes with a fill adhesive;
(4) arranging the OLED device in the middle of the substrate, and covering the OLED device with the passivation layer;
(5) aligning and pressing the substrate obtained in step (4) and the packaging cover plate obtained in step (3) together; and
(6) conducting UV light irradiation curing from one side of the packaging cover plate.

In the method for packaging the OLED display panel, a step (1′) is further implemented between step (1) and step (2), and in the step (1′), a second semipermeable membrane is arranged in the middle of the first semipermeable membrane.

In the method for packaging the OLED display panel, a distance between the semipermeable membranes and the passivation layer is not smaller than half of a height of the dam adhesive.

In the method for packaging the OLED display panel, an area of the second semipermeable membrane is smaller than that of the first semipermeable membrane.

In the method for packaging the OLED display panel, a thickness of the second semipermeable membrane is larger than that of the first semipermeable membrane.

The present disclosure has the following advantages. By providing the semipermeable membranes, part of UV light is blocked. The transmissivities in UV light of the semipermeable membranes are lower than the transmissivity of the peripheral areas of the cover plate where no semipermeable membrane is arranged. The fill adhesive in peripheral areas near the inner side of the dam adhesive can be cured faster than the fill adhesive in the center area, by way of which the diffusion speed of uncured fill adhesive to the peripheral areas from the center area can be controlled, and thus the fill adhesive can get into flawless contact with the dam adhesive that is not completely cured, and damage to the dam adhesive under the impact of the fill adhesive is prevented.

The semipermeable membranes are made of a metal material or a non-metal material and are low in cost and easy to arrange.

### BRIEF DESCRIPTION OF THE DRAWINGS

The present disclosure will be described in detail below based on embodiments with reference to the accompanying drawings. In the drawings:

FIG. 1 schematically shows a structure of an existing OLED display panel;

FIG. 2 schematically shows a structure of an OLED display panel of the present disclosure;

FIG. 3 schematically shows another structure of the OLED display panel of the present disclosure; and

FIG. 4 schematically shows a method for packaging the OLED display panel of the present disclosure.

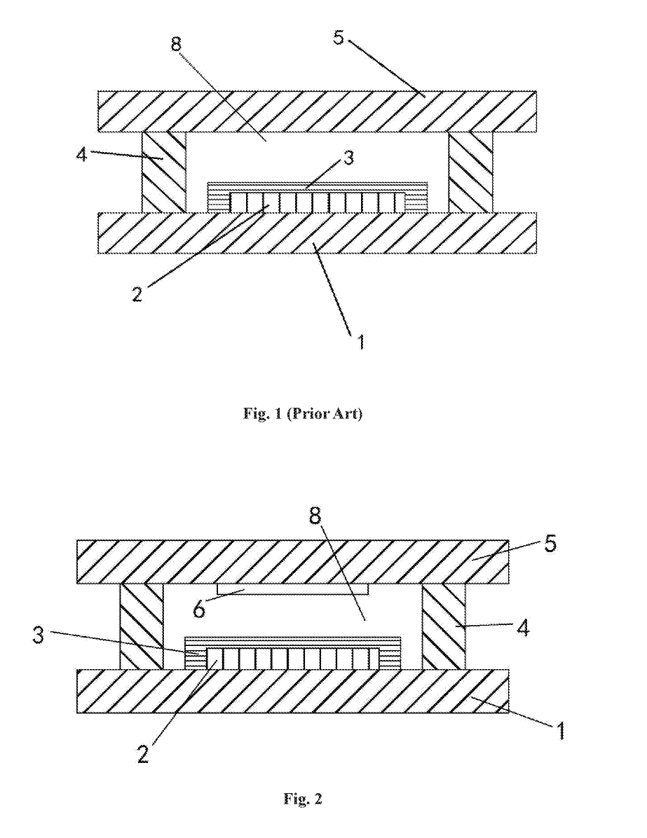

In the drawings, the same reference numerals are used to denote the same elements. The drawings are not drawn to scale.

### DETAILED DESCRIPTION OF THE EMBODIMENTS

The present disclosure is further described below according to the drawings.

As shown in FIG. 2, an OLED display panel comprises a substrate 1, an OLED device 2, a passivation layer 3, dam adhesive 4, fill adhesive 8, a cover plate 5 and a first semipermeable membrane 6.

The OLED device 2 is arranged in the middle of the substrate 1 and is covered by the passivation layer 3. The dam adhesive 4 is arranged on peripheries of the cover plate 5. A side of the cover plate 5, on which the dam adhesive 4 is provided, faces the substrate 1 provided with the OLED device 2. A sealed space is formed by the cover plate 5, the dam adhesive 4 and the substrate 1. The first semipermeable membrane 6 is arranged in the middle of the cover plate 5 and is located in the sealed space. The sealed space is filled with the fill adhesive 8. A height of the dam adhesive 4 is larger than a sum of thicknesses of the passivation layer 3, the first semipermeable membrane 6 and the OLED device 2. Furthermore, a certain distance is provided between the first semipermeable membrane 6 and the passivation layer 3 for storage of the fill adhesive 8. The distance between the first semipermeable membrane and the passivation layer is not smaller than half of the height of the dam adhesive.

A size of the first semipermeable membrane 6 is smaller than a size of a frame defined by the dam adhesive 4 on the cover plate 5.

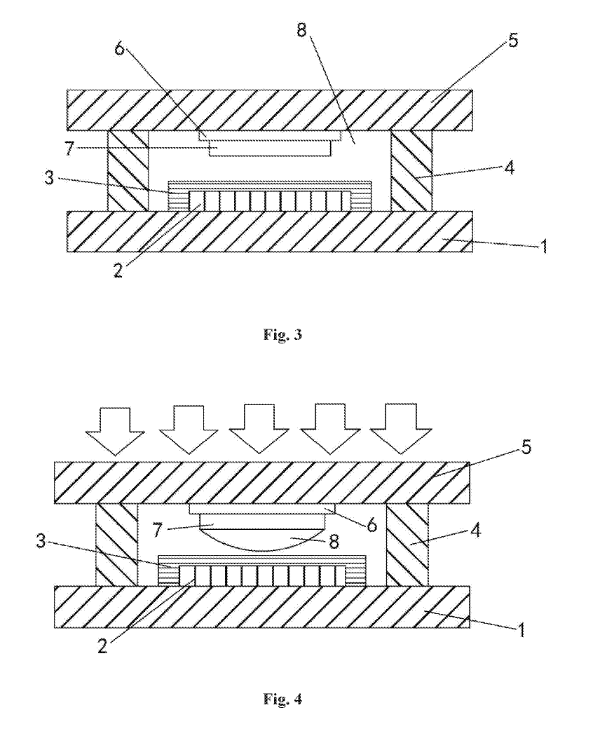

As shown in FIG. 3, a second semipermeable membrane 7 can further be arranged in the middle of the first semipermeable membrane 6, and an area of the second semipermeable membrane 7 is smaller than that of the first semipermeable membrane 6. In the OLED display panel, a thickness of the second semipermeable membrane 7 is larger than that of the first semipermeable membrane 6. The semipermeable membranes can be made of a metal material or a non-metal material and can block part of UV light. Due to the facts that the thickness of the second semipermeable membrane 7 is larger than that of the first semipermeable membrane 6, and the area of the second semipermeable membrane 7 is smaller than that of the first semipermeable membrane 6, transmissivity of the second semipermeable membrane 7 is smaller than that of the first semipermeable membrane 6, and a transmission gradient is formed. As transmissivities of the first semipermeable membrane and the second semipermeable membrane in UV light are lower than transmissivity of peripheral areas of the cover plate where no semipermeable membrane is arranged, during UV curing of the dam adhesive 4 and the fill adhesive 8, the fill adhesive in peripheral areas near an inner side (the side facing the sealed space) of the dam adhesive 4 is cured faster than the fill adhesive in an center area. Thus, diffusion speed of uncured fill adhesive to the peripheries areas from the center area is controlled, and the fill adhesive gets into flawless contact with the dam adhesive 4 that is not completely cured, preventing the dam adhesive from being damaged under impact of the fill dam.

As shown in FIG. 4, a method for packaging an OLED display panel comprises steps of:
(1) arranging a first semipermeable membrane 6 in the middle of a cover plate 5;
(2) coating the packaging cover plate 5 provided with the first semipermeable membrane 6 with a frame-shaped dam adhesive 4;
(3) coating an inner side of the frame-shaped dam adhesive 4 with a fill adhesive 8;
(4) arranging an OLED device 2 in the middle of the substrate, and covering the OLED device 2 with a passivation layer 3;
(5) aligning and pressing the substrate obtained in step (4) and the cover plate obtained in step (3) together; and
(6) conducting UV light irradiation curing from one side of the cover plate direction indicated by the arrow in FIG. 4 is a direction of the UV light irradiation).

The method for packaging the OLED display panel further comprises a step (1′) between step (1) and step (2). In the step (1′), a second semipermeable membrane 7 is arranged on the first semipermeable membrane 6. An area of the second semipermeable membrane 7 is smaller than that of the first semipermeable membrane 6. A thickness of the second semipermeable membrane 7 is larger than that of the first semipermeable membrane 6.

The semipermeable membranes can be made of a metal material or a non-metal material and can block part of UV light. Due to the facts that the thickness of the second semipermeable membrane is larger than that of the first semipermeable membrane, and the area of the second semipermeable membrane is smaller than that of the first semipermeable membrane, the transmissivity of the second semipermeable membrane is smaller than that of the first semipermeable membrane, and a transmission gradient is formed. As the transmissivities in UV light of the first semipermeable membrane and the second semipermeable membrane are lower than transmissivity of peripheral areas of the cover plate where no semipermeable membrane is arranged, during UV curing of the dam adhesive and the fill adhesive, the fill adhesive in peripheral areas near an inner side of the dam adhesive is cured faster than the fill adhesive in a center area. Thus, diffusion speed of uncured fill adhesive to the periphery areas from the center area can be controlled, and thus the fill adhesive gets into flawless contact with the dam adhesive that is not completely cured, preventing the dam adhesive from being damaged under the impact of the fill dam.

While the present disclosure has been described with reference to preferred embodiments, various modifications can be made within the scope of the disclosure, and equivalents may be substituted for components thereof. Particularly, as long as there is no structural conflict, all technical features mentioned in various embodiments can be combined in any modes. The present disclosure is not limited to the specific embodiments disclosed herein but includes all technical solutions that fall within the scope of the claims.

1. An OLED display panel, comprising a substrate, an OLED device, a passivation layer, a dam adhesive, a fill adhesive, a cover plate, and a first semipermeable membrane, wherein:
the OLED device is arranged in the middle of the substrate and is covered by the passivation layer;
the dam adhesive is provided on peripheries of the cover plate;
a side of the cover plate, on which the dam adhesive is provided, faces the to substrate provided with the OLED device;
a sealed space is formed by the cover plate, the dam adhesive, and the substrate;
the first semipermeable membrane is arranged in the middle of the cover plate and is located in the sealed space; and
the sealed space is filled with the fill adhesive.

2. The OLED display panel according to claim 1, wherein a size of the first semipermeable membrane is smaller than a size of a frame defined by the dam adhesive on the cover plate.

3. The OLED display panel according to claim 2, wherein a second semipermeable membrane is arranged in the middle of the first semipermeable membrane, wherein an area of the second semipermeable membrane is smaller than that of the first semipermeable membrane.

4. The OLED display panel according to claim 3, wherein a thickness of the second semipermeable membrane is larger than that of the first semipermeable membrane.

5. The OLED display panel according to claim 4, wherein a distance between the second semipermeable membrane and the passivation layer is not smaller than half of a height of the dam adhesive.

6. A method for packaging an OLED display panel, comprising:
(1) providing a first semipermeable membrane in the middle of a cover plate;
(2) coating the cover plate provided with the semipermeable membrane with a frame-shaped dam adhesive;
(3) coating the semipermeable membrane with a fill adhesive;
(4) providing an OLED device in the middle of the substrate, and covering the OLED device with a passivation layer;
(5) aligning and pressing the substrate obtained in step (4) and the cover plate obtained in step (3) together; and
(6) conducting UV light irradiation curing from one side of the cover plate.

7. The method for packaging the OLED display panel according to claim 6, further comprising a step (1′) between step (1) and step (2), wherein:
in step (1′), a second semipermeable membrane is provided in the middle of the first semipermeable membrane.

8. The method for packaging the OLED display panel according to claim 6, wherein a distance between the semipermeable membrane and the passivation layer is not smaller than half of a height of the dam adhesive.

9. The method for packaging the OLED display panel according to claim 7, wherein an area of the second semipermeable membrane is smaller than that of the first semipermeable membrane.

10. The method for packaging the OLED display panel according to claim 7, wherein a thickness of the second semipermeable membrane is larger than that of the first semipermeable membrane.
